(19) United States
(12) Patent Application Publication
(10) Pub. No.: US 2024/0096946 A1
(43) Pub. Date: Mar. 21, 2024

(54) DUAL DIELECTRIC STRESSORS

(71) Applicant: INTERNATIONAL BUSINESS MACHINES CORPORATION, ARMONK, NY (US)

(72) Inventors: Kangguo Cheng, Schenectady, NY (US); Ruilong Xie, Niskayuna, NY (US); Julien Frougier, Albany, NY (US); CHANRO PARK, CLIFTON PARK, NY (US); Min Gyu Sung, Latham, NY (US)

(21) Appl. No.: 17/932,677

(22) Filed: Sep. 16, 2022

(51) Int. Cl. H01L 29/06; H01L 21/8238; H01L 29/66; H01L 29/775; H01L 29/786

(52) U.S. Cl. CPC H01L 29/0673; H01L 21/823807; H01L 21/823814; H01L 29/66439; H01L 29/775; H01L 29/78696

(57) ABSTRACT

A lower set of semiconductor channel layers, an upper set of semiconductor channel layers, a lower dielectric layer adjacent to the lower set of semiconductor channel layers, the lower dielectric layer includes a first polarity stress on the lower set of semiconductor channel layers, and an upper dielectric layer adjacent to the upper set of semiconductor channel layers, the lower dielectric layer includes a second polarity stress on the upper set of semiconductor channel layers with opposite polarity stress of the first polarity stress. Forming a lower stack of nanosheet layers and an upper stack of nanosheet layers, forming a lower dielectric layer adjacent to the lower stack of nanosheet layers, the lower dielectric layer includes a first polarity stress, and forming an upper dielectric layer adjacent to the upper stack of nanosheet layers, the upper dielectric layer includes a second polarity stress with opposite polarity.

### BACKGROUND

The present invention relates, generally, to the field of semiconductor manufacturing, and more particularly to stacked Complementary Metal-oxide-semiconductor (CMOS) architecture with dual dielectric stressors.

CMOS technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet device contains one or more layers of semiconductor channel material portions having a vertical thickness that is substantially less than its width. A nanosheet FET includes a plurality of stacked nanosheets extending between a pair of source/drain epitaxial regions. The device may be a gate all around device or transistor in which a gate surrounds a portion of the nanosheet channel.

### SUMMARY

According to an embodiment, a semiconductor device is provided. The semiconductor device including a lower set of semiconductor channel layers vertically aligned and stacked one on top of another, the lower set of semiconductor channel layers separated from each other by a gate stack material wrapping around the lower set of semiconductor channel layers, an upper set of semiconductor channel layers vertically aligned and stacked one on top of another, the upper set of semiconductor channel layers separated from each other by the gate stack material wrapping around the upper set of semiconductor channel layers, the upper set of semiconductor channel layers vertically aligned above the lower set of semiconductor channel layers, a lower dielectric layer adjacent to a first vertical side and a second vertical side of the lower set of semiconductor channel layers, where the first vertical side and the second vertical side of the lower set of semiconductor channel layers are on opposite sides of the lower set of semiconductor channel layers, where the lower dielectric layer includes a first polarity stress on the lower set of semiconductor channel layers, and an upper dielectric layer adjacent to a first vertical side and a second vertical side of the upper set of semiconductor channel layers, wherein the first vertical side and the second vertical side of the upper set of semiconductor channel layers are on opposite sides of the upper set of semiconductor channel layers and vertically aligned above the lower dielectric layer, where the lower dielectric layer includes a second polarity stress on the upper set of semiconductor channel layers, where the first polarity stress and the second polarity stress are opposite polarity stresses from each other.

According to an embodiment, a semiconductor device is provided. The semiconductor device including a lower set of semiconductor channel layers vertically aligned and stacked one on top of another, the lower set of semiconductor channel layers separated from each other by a gate stack material wrapping around the lower set of semiconductor channel layers, an upper set of semiconductor channel layers vertically aligned and stacked one on top of another, the upper set of semiconductor channel layers separated from each other by the gate stack material wrapping around the upper set of semiconductor channel layers, the upper set of semiconductor channel layers vertically aligned above the lower set of semiconductor channel layers, a lower dielectric layer adjacent to a first vertical side and a second vertical side of the lower set of semiconductor channel layers, where the first vertical side and the second vertical side of the lower set of semiconductor channel layers are on opposite sides of the lower set of semiconductor channel layers, where the lower dielectric layer includes a first polarity stress on the lower set of semiconductor channel layers, and an upper dielectric layer adjacent to a first vertical side and a second vertical side of the upper set of semiconductor channel layers, where the first vertical side and the second vertical side of the upper set of semiconductor channel layers are on opposite sides of the upper set of semiconductor channel layers and vertically aligned above the lower dielectric layer, where the lower dielectric layer comprises a second polarity stress on the upper set of semiconductor channel layers, where the first polarity stress comprises a tensile stress and the second polarity stress comprises a compressive stress.

According to an embodiment, a method is provided. The method including forming a lower stack of nanosheet layers on a substrate and an upper stack of nanosheet layers vertically aligned above the lower stack of nanosheet layers, the first stack and the second stack of nanosheet layers each including alternating layers of a sacrificial and a semiconductor channel vertically aligned and stacked one on top of another, forming a lower dielectric layer vertically adjacent to the lower stack of nanosheet layers, where the lower dielectric layer includes a first polarity stress, and forming an upper dielectric layer vertically adjacent to the upper stack of nanosheet layers, wherein the upper dielectric layer includes a second polarity stress which is an opposite polarity of the first polarity stress, where the upper dielectric layer is vertically aligned above the lower dielectric layer.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a cross-sectional view of a semiconductor structure at an intermediate stage of fabrication, according to an exemplary embodiment;

FIG. 2 illustrates a cross-sectional view of the semiconductor structure, according to an exemplary embodiment, and illustrates forming a sacrificial gate, gate side spacers, a bottom dielectric isolation, a middle dielectric isolation, an upper source drain, a lower source drain and an interlayer dielectric;

FIG. 3 illustrates a cross-sectional view of the semiconductor structure, according to an exemplary embodiment, and illustrates forming an organic planarization layer, and a first diffusion break;

FIG. 4 illustrates a cross-sectional view of the semiconductor structure, according to an exemplary embodiment, and illustrates forming a first dielectric;

FIG. 5 illustrates a cross-sectional view of the semiconductor structure, according to an exemplary embodiment, and illustrates recessing the first dielectric to form a second diffusion break;

FIG. 6 illustrates a cross-sectional view of the semiconductor structure, according to an exemplary embodiment, and illustrates forming a second dielectric;

FIG. 7 illustrates a cross-sectional view of the semiconductor structure, according to an exemplary embodiment, and illustrates removing the sacrificial gate and sacrificial layers;

FIG. 8 illustrates a cross-sectional view of the semiconductor structure, according to an exemplary embodiment, and illustrates forming a replacement gate; and

FIG. 9 illustrates a cross-sectional view of the semiconductor structure, according to an exemplary embodiment, and illustrates forming a frontside interconnect layer, a backside interconnect layer and contacts; and

FIG. 10 illustrates the cross-sectional view of FIG. 9 of the semiconductor structure, according to an exemplary embodiment, and transfer of stresses from the first dielectric and from the second dielectric to nanosheet channel layers.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numbers may be repeated among the figures to indicate corresponding or analogous features.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The present invention relates, generally, to the field of semiconductor manufacturing, and more particularly to stacked Complementary Metal-oxide-semiconductor (CMOS) architecture with dual dielectric stressors.

This invention provides a structure and method for improve both negative field effect transistors (hereinafter “n-FET”) and positive field effect transistors (hereinafter “p-FET”) in a stacked CMOS architecture by implementing two different dielectric stressors in diffusion breaks. A first dielectric stressor produces longitudinal tensile stress to channel layers of the n-FET channel and a second dielectric stressor produces longitudinal compressive stress to channel layers of the p-FET channel. As a result, electron mobility and hole mobility are enhanced by each dielectric stressor, respectively. Thus, performance of both n-FET and p-FET are enhanced simultaneously. A diffusion break DB isolates two neighboring devices in a standard cell-based design.

Stress on the semiconductor channel layer improves performance of the nanosheet FET by generating strain in the channel, improving carrier mobility in the channel and thereby increasing device performance. Strain engineering allows local modification of the band structure in the channel region, affecting the effective mass of the carriers and hence the carrier mobility during transport in the channel region.

A nanosheet field effect transistor (hereinafter “FET”) may be formed from alternating layers of silicon and silicon germanium, which are then formed into stacked nanosheets. A gate all around structure may be formed on all vertical sides and on a horizontal top surface of a section of the nanosheets. Source-drain structures may be formed at the opposite ends of the stacked nanosheet structures.

Forming the nanosheet FET may have the following steps. Layers of the stacked nanosheet are formed on a substrate, trenches are formed parallel to each other in the layers of the stacked nanosheet to form fins and sacrificial gates are then formed perpendicular to the trenches. Additional trenches are formed between sacrificial gates, perpendicular to the original trenches. Outer portions of sacrificial layers of the stacked nanosheets may be removed and inner spacers formed where the outer portions of the sacrificial layers of the stacked nanosheets where removed. Lower and upper source drain regions are formed extending out from exposed channel layers of the nanosheet stacks.

In an embodiment, openings for a diffusion break may be formed in the nanosheet FET. The openings may be formed along alternating nanosheet stacks by removing vertically aligned portions, of the sacrificial gate, the layers of the stacked nanosheet and a portion of the substrate. A first dielectric with a first type of stress may be formed in a lower portion of the openings. For example, if a lower portion of the stacked nanosheet is an n-FET device, the first dielectric will produce tensile stress to the n-FET channel layers. A second dielectric with a second type of stress may be formed in an upper portion of the openings. In this example, if an upper portion of the stacked nanosheet is a p-FET device, the second dielectric will produce compressive street to the p-FET channel layers. Stressors from the first dielectric and from the second dielectric are transferred to the nanosheet channels. For any n-FET devices, a tensile stress would be applied and for any p-FET devices a compressive stress would be applied. The first dielectric and the second dielectric may have opposite polarity stress from each other.

The sacrificial gates are removed, and remaining portions of the sacrificial layers are removed. A replacement gate may be formed where the sacrificial gates and the remaining portions of the sacrificial layers were removed, surrounding the channel layers. An interlayer dielectric may be formed on the structure. Contacts may be formed to the metal gate and to each the upper source drain and the lower source drain. Frontside interconnect layers of wiring and vias may be formed on the interlay dielectric. The structure may be flipped upside down and further processing may be done to a lower portion of the structure. The substrate may be removed. A second interlayer dielectric may be formed on the lower portion of the structure. Contacts may be formed to the lower source drain through the second interlayer dielectric. Backside interconnect layers of wiring and vias may be formed on the second interlayer dielectric.

Forming a FET nanosheet with dual dielectric stressors enhance both n-FET and p-FET performance by using different materials to produce a tensile stress to n-FET channel layers and a compressive stress to p-FET channel layers.

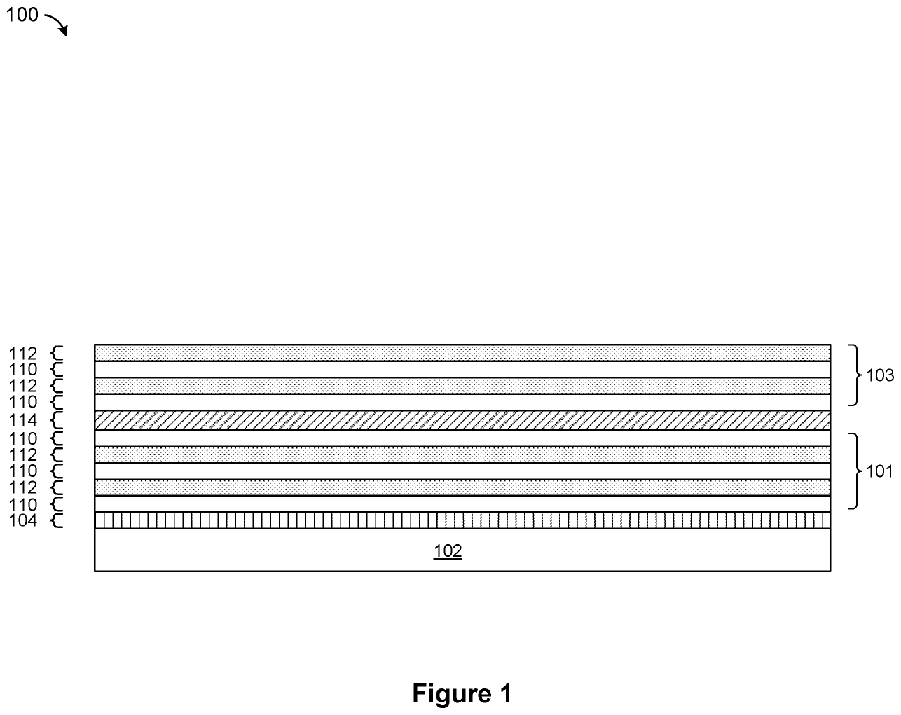

Embodiments of the present invention disclose a structure and a method of forming a FET nanosheet or CMOS architecture devices with dual dielectric stressors are described in detail below by referring to the accompanying drawings in FIGS. 1-10, in accordance with an illustrative embodiment.

Referring now to FIG. 1, a cross-sectional view of a semiconductor structure 100 (hereinafter “structure”) at an intermediate stage of fabrication is shown according to an exemplary embodiment. The structure 100 of FIG. 1 may be formed or provided. The structure 100 may include alternating layers of sacrificial semiconductor material and semiconductor channel material stacked one on top of another on a substrate 102.

The substrate 102 may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium arsenide. Typically, the substrate 102 may be approximately, but is not limited to, several hundred microns thick. In other embodiments, the substrate 102 may be a layered semiconductor such as a silicon-on-insulator or SiGe-on-insulator, where a buried insulator layer, separates a base substrate from a top semiconductor layer.

The alternating layers of sacrificial semiconductor material and semiconductor channel material may include a bottom sacrificial layer 104, covered by a sacrificial semiconductor material layer 110 (hereinafter “sacrificial layer”), covered by a semiconductor channel material layer 112 (hereinafter “channel layer”), covered by a sacrificial layer 110, covered by a channel layer 112, covered by a sacrificial layer 110, covered by a stack sacrificial layer 114, covered by a sacrificial layer 110, covered by a channel layer 112, covered by a sacrificial layer 110, covered by a channel layer 112. It should be noted that, while a limited number of alternating layers are depicted, any number of sacrificial layers 110 and channel layers 112 may be formed.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition technique, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth techniques include, for example, rapid thermal chemical vapor deposition (RTCVD), low-energy plasma deposition (LEPD), ultra-high vacuum chemical vapor deposition (UHVCVD), low pressure chemical vapor deposition (LPCVD), atmospheric pressure chemical vapor deposition (APCVD) and molecular beam epitaxy (MBE). The temperature for epitaxial deposition typically ranges from approximately 550° C. to approximately 900° C. Although higher temperature typically results in faster deposition, the faster deposition may result in crystal defects and film cracking. The epitaxial growth the first and second semiconductor materials that provide the sacrificial semiconductor material layers and the semiconductor channel material layers, respectively, can be performed utilizing any well-known precursor gas or gas mixture. Carrier gases like hydrogen, nitrogen, helium and argon can be used.

Each sacrificial layer 110 is composed of a first semiconductor material which differs in composition from at least an upper portion of the substrate 102, the channel layer 112, the bottom sacrificial layer 104 and the stack sacrificial layer 114. In an embodiment, each sacrificial layer 110 may be a silicon-germanium semiconductor alloy and have a germanium concentration less than 50 atomic percent. In another example, each sacrificial layer 110 may have a germanium concentration ranging from about 20 atomic percent to about 40 atomic percent. Each sacrificial layer 110 can be formed using known deposition techniques or an epitaxial growth technique as described above.

Each channel layer 112 is composed of a second semiconductor material which differs in composition from at least the upper portion of the substrate 102, the sacrificial layer 110, the bottom sacrificial layer 104 and the stack sacrificial layer 114. Each channel layer 112 has a different etch rate than the first semiconductor material of sacrificial layer 110, has a different etch rate than the stack sacrificial layer 114 and has a different etch rate than the bottom sacrificial layer 104. The second semiconductor material can be, for example, silicon. The second semiconductor material, for each channel layer 112 can be formed using known deposition techniques or an epitaxial growth technique as described above.

The bottom sacrificial layer 104 and the stack sacrificial layer 114, may each be, for example, silicon germanium with a germanium concentration about 60 atomic percent, although percentages greater than 60 percent and less than 60 percent may be used. The bottom sacrificial layer 104 and the stack sacrificial layer 114 can be formed using an epitaxial growth technique. The bottom sacrificial layer 104 and the stack sacrificial layer 114 will each subsequently be removed selective to the remaining alternating layers, as described below. The bottom sacrificial layer 104 and the stack sacrificial layer 114 may be formed of different materials, or of the same material.

The alternating layers of sacrificial layer 110, channel layers 112, the bottom sacrificial layer 104 and the stack sacrificial layer 114 can be formed by sequential epitaxial growth of alternating layers of the first semiconductor material, the second semiconductor material, the bottom sacrificial layer 104 and the stack sacrificial layer 114 material.

The sacrificial layers 110 may have a thickness ranging from about 5 nm to about 15 nm, and the channel layers 112 may have a thickness ranging from about 3 nm to about 15 nm. Each sacrificial layer 110 may have a thickness that is the same as, or different from, a thickness of each channel layer 112. In an embodiment, each sacrificial layer 110 has an identical thickness. In an embodiment, each channel layer 112 has an identical thickness. The stack sacrificial layer (not shown) may have a thickness ranging from about 3 nm to about 15 nm.

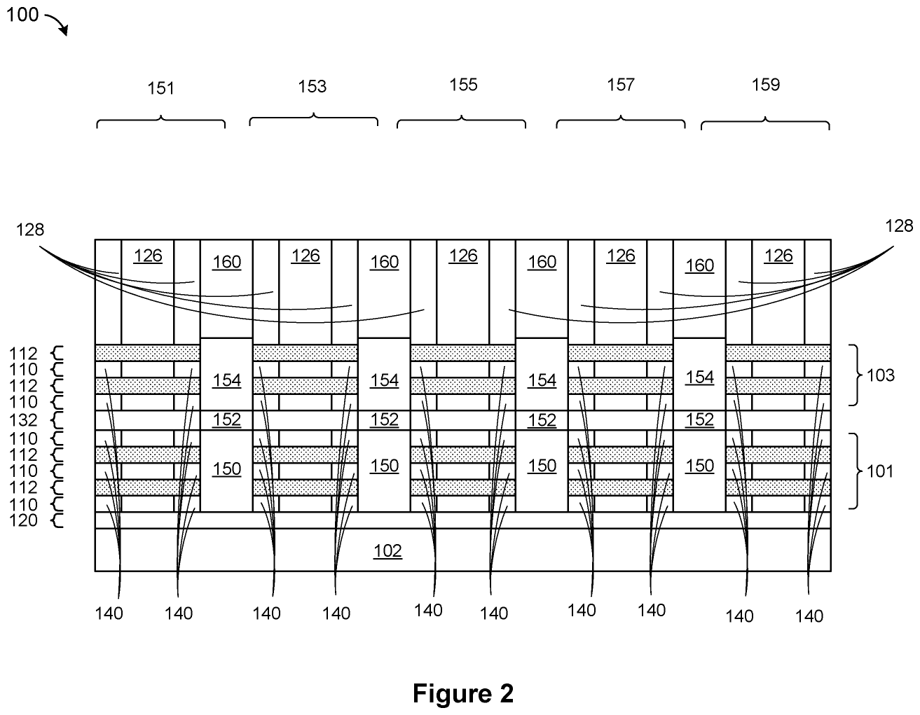

Referring now to FIG. 2, a cross-sectional view of the structure 100 is shown according to an exemplary embodiment. The alternating layers of sacrificial layers 110, channel layers 112, the bottom sacrificial layer 104 and the stack sacrificial layer 114 may be formed into nanosheet fins, by methods known in the arts and include steps such as forming a hard mask (not shown) on the alternating layers, patterning the hard mask (not shown). The hard mask (not shown) may be removed. A shallow trench isolation region (hereinafter “STI”), which is not shown, may be formed between nanosheet fins. A sacrificial gate 126 is then patterned, followed by selective removal of bottom sacrificial layer 104 and the stack sacrificial layer 114. Gate side spacers 128, bottom dielectric isolation (hereinafter “BDI”) 120, and a middle dielectric isolation layer 132 are formed by a conformal dielectric deposition and anisotropic dielectric etching process. Portions of the upper, lower nanosheet stack 103, 102 that are not protected by the sacrificial gate 126, the gate side spacer 128 and the channel layers 112 are selectively recessed, followed by sacrificial layer 112 indentation, and inner spacers 140 formation. A lower source drain 150, an interlayer dielectric (hereinafter “ILD”) 152, an upper source drain 154 and an interlayer dielectric (hereinafter “ILD”) 160 may be formed.

The material stacks that can be employed in embodiments of the present invention are not limited to the specific embodiment illustrated in FIG. 2. In FIG. 2, and only by way of an example, the lower nanosheet stack 101 includes three layers of sacrificial layers 110 alternating with two layers of the channel layers 112, and the upper nanosheet stack 103 includes two layers of sacrificial layers 110 alternating with two channel layers 112. The lower nanosheet stack 101 may be separated from the upper nanosheet stack 103 by the stack sacrificial layer 114.

The sacrificial gate 126 is formed orthogonal (perpendicular) to the nanosheet stacks. By way of illustration, five sacrificial gates 126 are depicted in the drawings of the present application. The sacrificial gate 126 may include a single sacrificial material or a stack of two or more sacrificial materials. The at least one sacrificial material can be formed by forming a blanket layer (or layers) of a material (or various materials) and then patterning the material (or various materials) by lithography and an etch. The sacrificial gate 126 can include any material including, for example, polysilicon, amorphous silicon, or multilayered combinations thereof. The sacrificial gate 126 can be formed using any deposition technique including, for example, chemical vapor deposition (CVD), physical vapor deposition (PVD), high density plasma (HDP) deposition, and spin on techniques. Optionally, a gate dielectric layer (not shown) and a gate cap (not shown) may be formed as part of the sacrificial gate 126 in accordance with known techniques.

In an embodiment, the sacrificial gate 126 is deposited with a thickness sufficient to fill, or substantially fill, the spaces between adjacent nanosheet structures and cover a horizontal upper surface of the substrate 102. The sacrificial gate 126 may be adjacent to vertical side surfaces of the nanosheet stack, including the lower nanosheet stack 101, the upper nanosheet stack 103 and the stack sacrificial layer 114. The sacrificial gate 126 and surrounding gate side spacers 128 may cover an upper horizontal surface of an uppermost channel layer 112 of the nanosheet stack. A height of the sacrificial gate 126 may be much thicker than the underlying structure and may have a height between 100 nm and 150 nm about the nanosheet stack. The gate cap (not shown) may cover an upper horizontal surface and a vertical side surface of the sacrificial gate 126.

The bottom sacrificial layer 104 and the stack sacrificial layer 114 between the upper nanosheet stack 103 and the lower nanosheet stack 101 may be selectively removed using one or more known techniques selective to the channel layers 112, the sacrificial layers 110, the sacrificial gate 126, the gate side spacers 128 and the substrate 102. For example, a dry etching technique can be used to selectively remove the stack sacrificial layer (not shown), such as, for example, using vapor phased HCl dry etch. The bottom sacrificial layer 104 and the stack sacrificial layer may be removed simultaneously or sequentially.

An insulator layer may be formed where the bottom sacrificial layer 104 and the stack sacrificial layer 114 were removed. The insulator layer may be formed after several processes, including for example, conformally depositing or growing a dielectric and performing an anisotropic etch back process. The insulator layer may include any dielectric material such as silicon nitride (SiN), silicon boron carbon nitride (SiBCN), silicon oxide carbon nitride (SiOCN), aluminum oxide (AlOx), and may include a single layer or may include multiple layers of dielectric material. The insulator layer may have a thickness ranging from about 3 nm to about 15 nm. This process will form the gate side spacers 128, the middle dielectric isolation layer 132, and the BDI 120. In an embodiment, the gate side spacers 128, the middle dielectric isolation layer 132, and the BDI 120 may be formed simultaneously. In an alternate embodiment, the gate side spacers 128, the middle dielectric isolation layer 132, and the BDI 120 may be formed individually.

The gate side spacers 128 may be formed vertically aligned with the sacrificial gate 126. The middle dielectric isolation layer 132 may be formed with the stack sacrificial layer 114 was removed. The BDI may be formed where the bottom sacrificial layer 104 was removed. The gate side spacers 128 may have a vertical side surface aligned with vertical side surfaces of the channel layers 112 and of the channel layers 110. The gate side spacers 128 may have a vertical side surface adjacent to a vertical side surface of the sacrificial gate 126.

A source drain trench (not shown) may be formed along the nanosheet fin, separating the nanosheet fin into nanosheet stacks. The source drain trench (not shown) may be formed by an anisotropic etching technique, such as, for example, reactive ion etching (RIE). A lowermost surface of the source drain trench (not shown) may reach to the BDI 120. The anisotropic etching may remove aligned vertical portions of the stacked nanosheet fin between adjacent sacrificial gates 126 and gate side spacers 128. The sacrificial gate 126 and the gate side spacers 128 may protect remaining portions of the nanosheet stack.

The lower nanosheet stack 101 and the upper nanosheet stack 103 each can include any number of sacrificial layers 110 and channel layers 112. The nanosheet stack is used to produce a gate all around device that includes vertically stacked semiconductor channel material nanosheets for a pair of stacked p-FETs or a pair of stacked n-FETs, or a p-FET stacked on an n-FET or an n-FET stacked on a p-FET.

Portions of the sacrificial layers 110 may be selectively removed using known techniques. For example, a wet or dry etch process can be used with the appropriate chemistry to remove portions of each of the sacrificial layers 110. The material used for the etching process may be selective such that the channel layers 112, the middle dielectric isolation layer 132, the sacrificial gate 126, the gate side spacers 128, the BDI 120 and the substrate 102 remain and are not etched. After etching, portions of the sacrificial layers 110 covered on opposite sides by the sacrificial gate 126 may remain as part of the nanosheet stack. In such cases, the sacrificial gate 126 supports the remaining channel layers 112 and the middle dielectric isolation layer 132 of the nanosheet stack.

An inner spacer 140 may be formed where the portions of the sacrificial layers 110 have been removed. The inner spacer 140 may be formed by conformally depositing or growing a dielectric material, followed by a combination of dry and wet isotropic etch back steps. The inner spacer 140 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an isotropic etch back process such as a reactive ion etch (RIE) and/or wet etch process, or any suitable etch process. In an embodiment, the inner spacer 140 may include one or more layers. In an embodiment, the inner spacer 140 may include any dielectric material such as silicon oxide, silicon oxynitride, silicon nitride, SiBCN, SiOC, low-k dielectric or any combination of these materials. In an embodiment, the inner spacer 140 may be nitride. In an alternate embodiment, the inner spacer 140 may be oxide.

The inner spacer 140 may completely fill in spaces between the channel layers 112, between the upper most channel layer 112 and the sacrificial gate 126, and between the lowermost channel layer 112 and the substrate 102, where the portions of the sacrificial layers 110 had been previously removed.

A vertical side surface of the inner spacer 140 may be aligned with a vertical side surface of the channel layers 112 and a vertical side surface of the gate side spacer 128.

The lower source drain 150 may be epitaxially grown surrounding a vertical portion of the lower nanosheet stack 101 on opposite sides of the sacrificial gate 126 in the source drain trench (not shown) on the BDI 120. In this embodiment, the lower source drain 150 may surround the lower most two channel layers 112 and the lower most three sacrificial layers 110 with surrounding inner spacers 140 of the lower nanosheet stack 101. During lower source drain 150 epitaxial growth, the upper nanosheet stack 103 may be protected by a sacrificial layer, or any epitaxial growth on the upper nanosheet stack 103, which may be subsequently recessed using, for example, a dry etch process.

The ILD 152 may be formed by depositing or growing a dielectric material, followed by a combination of dry and wet etch and recessing steps on the lower source drain 150 in the source drain trench (not shown). The ILD 152 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an etch process such as wet etch or a reactive ion etch (RIE), or any suitable etch process. In an embodiment, the ILD 152 may include one or more layers. In an embodiment, the ILD 152 may include any dielectric material such as silicon oxide, silicon oxynitride, silicon nitride, SiBCN, SiOC, low-k dielectric or any combination of these materials. In an embodiment, the ILD 152 may be a nitride. In an alternate embodiment, the ILD 152 may be an oxide. The ILD 152 may surround the middle dielectric isolation layer 132 and the surrounding sacrificial layers 110 with surrounding inner spacers 140.

The upper source drain 154 may be epitaxially grown surrounding a vertical portion of the upper nanosheet stack 103 on opposite sides of the sacrificial gate 126 in the source drain trench (not shown). In this embodiment, the upper source drain 154 may surround the upper most two channel layers 112 and the upper most two sacrificial layers 110 with surrounding inner spacers 140 of the upper nanosheet stack 103. The upper source drain 154 may be adjacent to an upper surface of the lower source drain 150. An upper surface of the upper source drain 154 may be higher than an upper surface of the uppermost channel layer 112.

The ILD 160 may be formed in a remaining portion of the source drain trench (not shown) on the upper source drain 154, adjacent to the gate side spacers 128.

A chemical mechanical polishing (CMP) technique may be used to remove excess material and polish upper surfaces of the structure 100, removing the gate cap (not shown) and exposing an upper horizontal surface of the sacrificial gate 126, the gate side spacers 128 and the ILD 160.

There are five nanosheet FET regions 151, 153, 155, 157, 159 illustrated in FIG. 2. There may be any number of nanosheet FET regions 151, 153, 155, 157 on the structure 100. The nanosheet FET regions 151, 153, 155, 157 identify vertically aligned upper nanosheet stack 103 and lower nanosheet stack 101 between two vertically aligned lower source drain 150, ILD 152, upper source drain 154 and ILD 160.

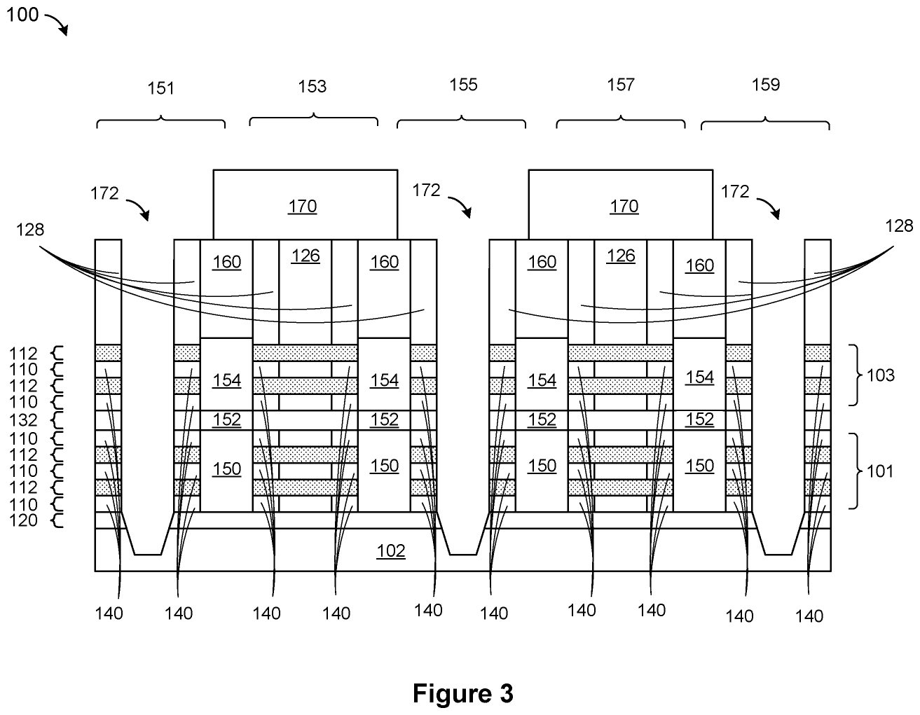

Referring now to FIG. 3, a cross-sectional view of the structure 100 is shown according to an exemplary embodiment. A first diffusion break 172 may be formed. A lithography soft mask, such as an organic planarization layer 170 (hereinafter “OPL”) may be used for the patterning process. The OPL 170 may be formed by a blanket deposition using typical deposition techniques, for example spin-on coating. The OPL 170 can be a self-planarizing organic material that includes carbon, hydrogen, oxygen, and optionally nitrogen, fluorine, and silicon. The OPL 170 can be a standard CₓM_{y} polymer. Non-limiting examples of materials include, but are not limited to, CHM701B, commercially available from Cheil Chemical Co., Ltd., HM8006 and HM8014, commercially available from JSR Corporation, and ODL-102 or ODL-401, commercially available from ShinEtsu Chemical, Co., Ltd.

A lithograph patterning and dry etch technique may be used to selectively remove a portion of the OPL 170 which is subsequently used to form the first diffusion break 172. The first diffusion break 172 may be formed between alternating nanosheet FET regions. Specifically, the first diffusion break 172 may be formed along nanosheet FET regions 151, 155, 159. The first diffusion break 172 may not be formed along nanosheet FET regions 153, 157. The first diffusion break 172 may have vertically aligned exposed side surfaces of the gate side spacers 128, the channel layers 112, the inner spacers 140, the middle dielectric isolation layer 132, the BDI 120 and the substrate 102. A lower surface of the first diffusion break 172 may be an upper surface of the substrate 102.

The first diffusion break 172 may be formed by an anisotropic etching technique, such as, for example, reactive ion etching (RIE), removing aligned portions of the OPL 170 and stopping on etching a portion of the silicon substrate 102. The etch process is self-aligned process. It selectively etching the sacrificial gate 126 and the upper, lower nanosheet stacks 103, 101, with respect to the ILD 160, inner spacer 140 and gate side spacer 128.

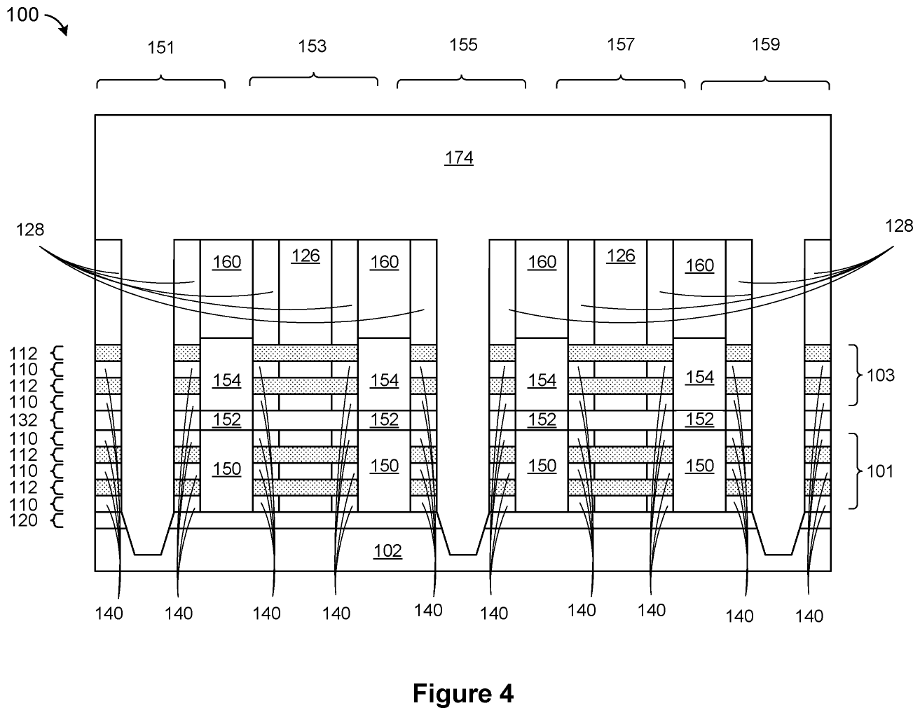

Referring now to FIG. 4, a cross-sectional view of the structure 100 is shown according to an exemplary embodiment. The OPL 170 may be removed. A first dielectric 174 may be formed.

The OPL 170 may be selectively removed by a combination of wet/dry etch, such that the gate side spacers 128, the sacrificial gate 126, the channel layers 112, the inner spacers 140, the middle dielectric isolation layer 132, the BDI 120 and the substrate 102 remain and are not etched.

The first dielectric 174 may be formed by conformally depositing or growing a dielectric material, filling the first diffusion break 172. The first dielectric 174 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the first dielectric 174 may include one or more layers. In an embodiment, the first dielectric 174 may include any dielectric material such as silicon oxide, silicon oxynitride, silicon nitride, SiBCN, SiOC, low-k dielectric or any combination of these materials. A lower surface of the first dielectric 174 may be adjacent to an upper surface of the substrate 102. A vertical side surface of the first dielectric 174 may be adjacent to vertical side surfaces of the BDI 120, the inner spacers 140 of the lower nanosheet stack 101, the channel layers 112 of the lower nanosheet stack 101, the middle dielectric isolation layer 132, and the gate side spacer 128. A lower horizontal surface of the first dielectric 174 may be adjacent to an upper surface of the gate side spacer 128.

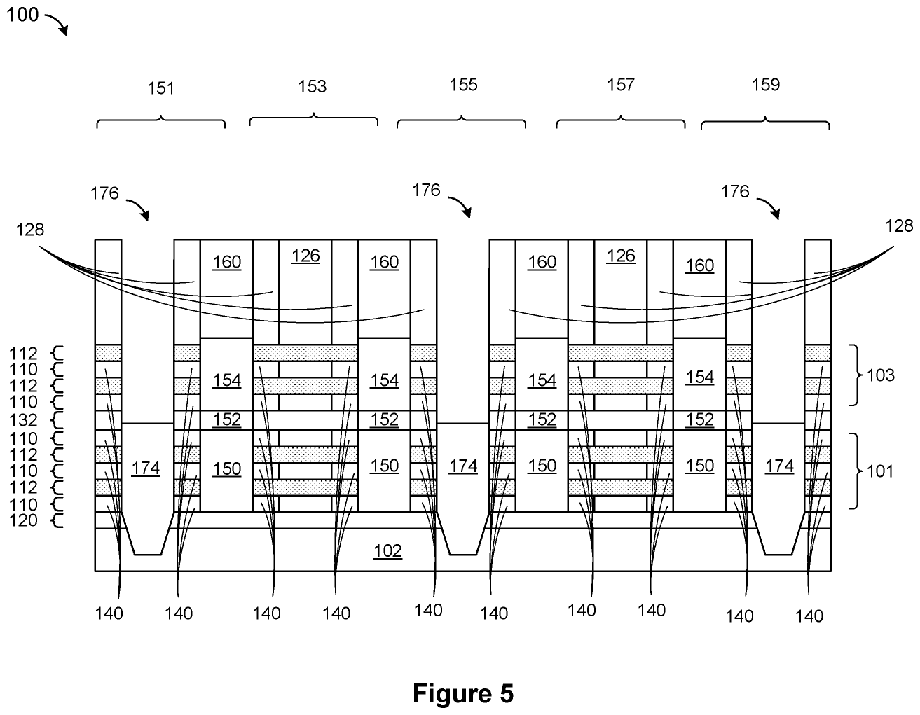

Referring now to FIG. 5, a cross-sectional view of the structure 100 is shown according to an exemplary embodiment. The first dielectric 174 may be recessed, forming a second diffusion break 176.

The first dielectric 174 may be recessed with a combination of processes. For example, a chemical mechanical polishing (CMP) technique may be used to remove excess material and polish upper surfaces of the structure 100, removing portions of the first dielectric 174 and exposing an upper horizontal surface of the gate side spacers 128, the sacrificial gate 126 and the ILD 160.

The first dielectric 174 may be further recessed by a combination of dry and wet etch and recessing steps, selective to the gate side spacers 128, the channel layers 112, the inner spacers 140, the middle dielectric isolation layer 132, the ILD 160, the sacrificial gate 126. The removal of the portions of the first dielectric 174 may form the second diffusion break 176. A remaining portion of the first dielectric 174 may have an upper horizontal surface along a vertical side surface of the middle dielectric isolation layer 132.

The second diffusion break 176 may be a vertically aligned opening, along exposed vertical side surfaces of the gate side spacer 128, the channel layers 112 and the middle dielectric isolation layer 132. A lower surface of the second diffusion break 176 may be an upper surface of the first dielectric 174.

The first dielectric 174 may provide an isolation between nanosheet FET regions. For example between nanosheet FET regions 153, 157.

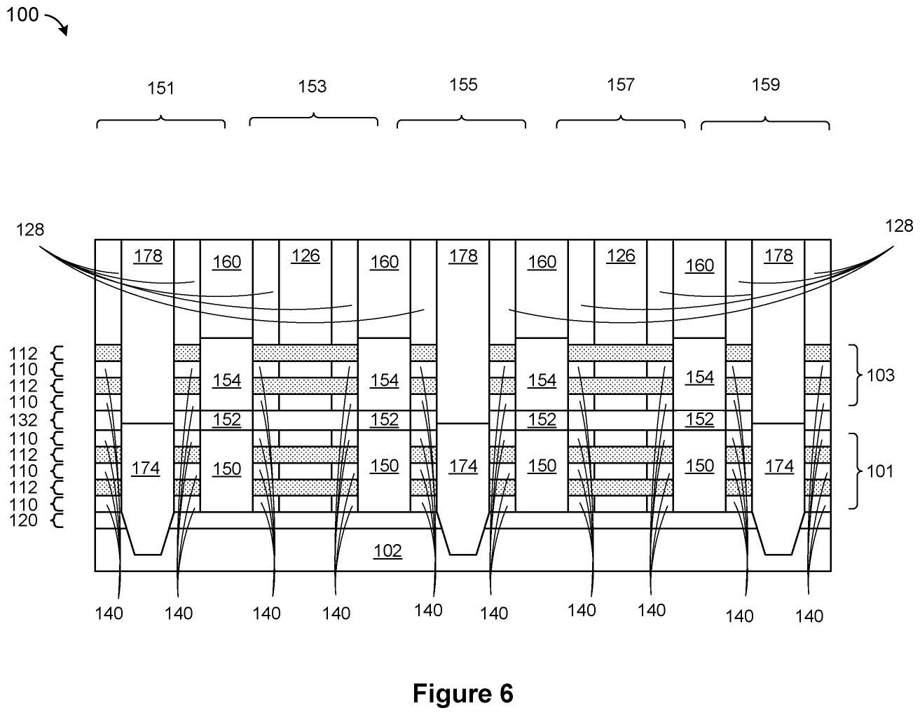

Referring now to FIG. 6, a cross-sectional view of the structure 100 is shown according to an exemplary embodiment. A second dielectric 178 may be formed in the second diffusion break 176.

The second dielectric 178 may be formed as described for the first dielectric 174. A lower surface of the first dielectric 174 may be adjacent to an upper surface of the substrate 102. A vertical side surface of the second dielectric 178 may be adjacent to vertical side surfaces of the inner spacers 140 of the upper nanosheet stack 103, the channel layers 112 of the upper nanosheet stack 103, the middle dielectric isolation layer 132, and the gate side spacer 128. A lower horizontal surface of the second dielectric 178 may be adjacent to an upper surface of the first dielectric 174.

A chemical mechanical polishing (CMP) technique may be used to remove excess material and polish upper surfaces of the structure 100. An upper surface of the structure 100 may include an horizontal surfaces of the ILD 160, the sacrificial gate 126, the gate side spacers 128 and the second dielectric 178.

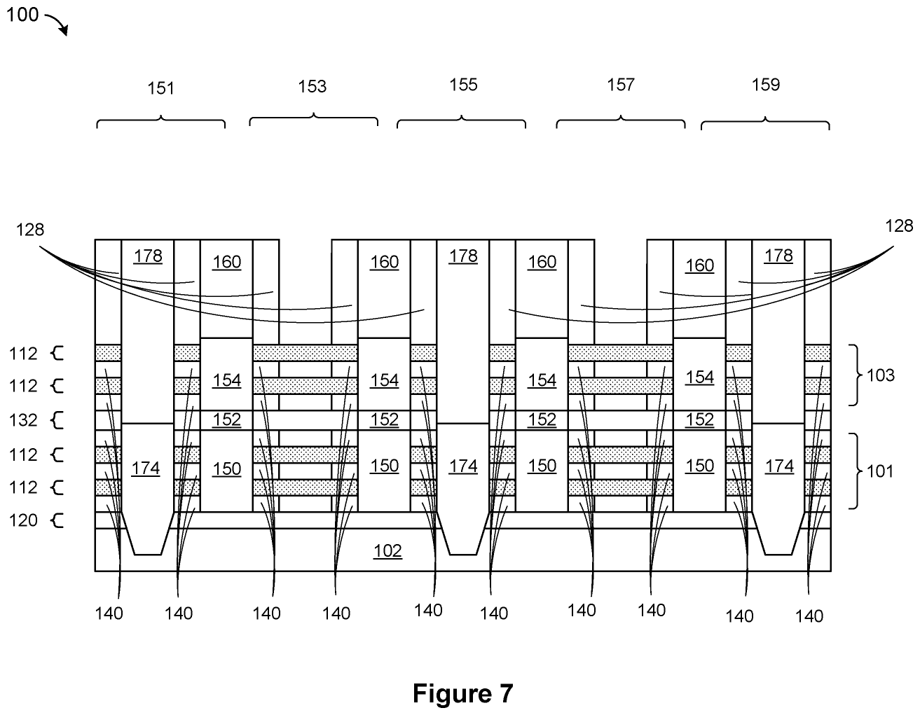

Referring now to FIG. 7, a cross-sectional view of the structure 100 is shown according to an exemplary embodiment. The sacrificial gate 126 may be removed. The sacrificial layers 110 may be removed.

The sacrificial gate 126 may be removed by methods known in the arts. The sacrificial layers 110 may be removed by methods known in the arts. The sacrificial gate 126 and the sacrificial layers may be removed simultaneously or consecutively. The sacrificial gate 126 and the sacrificial layers 110 are removed selective to the channel layers 112, the inner spacers 140, the ILD 160, the middle dielectric layer 132, the BDI 120, the upper source drain 154, the lower source drain 150, the ILD 152, the second dielectric 178, the first dielectric 174 and the silicon substrate 102. For example, a dry etch process can be used to selectively remove the sacrificial gate 126 and the sacrificial layers 110, such as using vapor phased HCl dry etch. An upper surface and a lower surface of the channel layers 112 may be exposed. An upper surface and a lower surface of the middle dielectric layer 132 may be exposed An upper surface of the BDI 120 may be exposed. Vertical side surfaces of the gate side spacer 128 and the inner spacers 140 may be exposed.

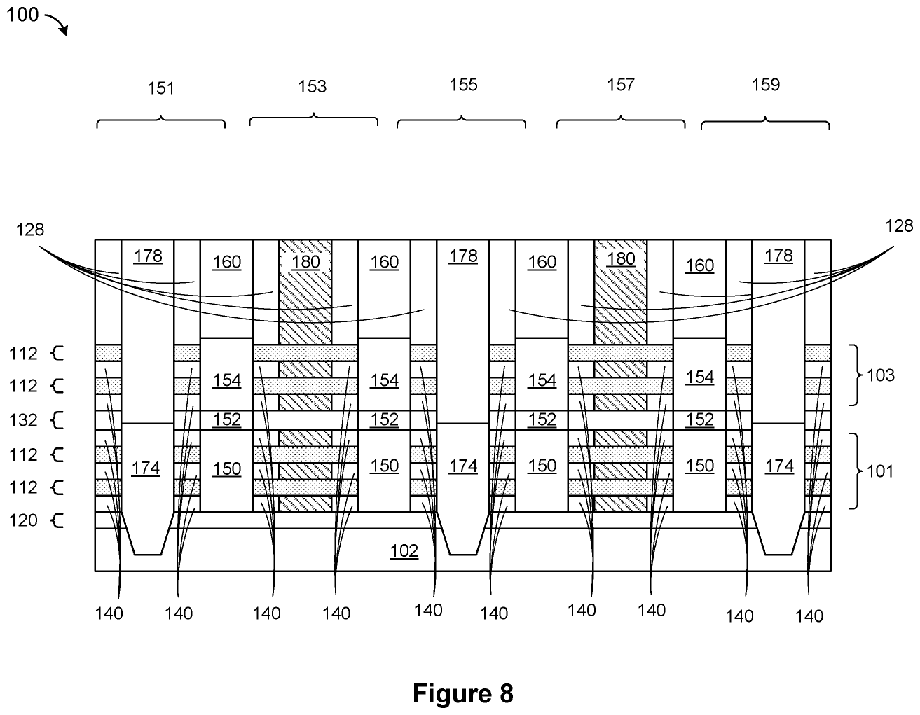

Referring now to FIG. 8, a cross-sectional view of the structure 100 is shown according to an exemplary embodiment. A replacement gate 180 may be formed.

The replacement gate 180 may be conformally formed on the structure 100, according to an exemplary embodiment. The replacement gate 180 is formed in each cavity of the nanosheet stack and surrounding suspended portions of the channel layers 112 and surrounding suspended portions of the middle dielectric layer 132. The replacement gate 180 forms a layer surrounding exposed portions of the nanosheet stacks. The replacement gate 180 may cover an exposed upper horizontal surface of the BDI 120, exposed vertical side surfaces of one side of each of the side spacers 140, and exposed vertical surfaced of one side of the gate side spacers 128. The replacement gate 180 may cover vertical side surfaces, an upper horizontal surface and a lower horizontal surface of the channel layers 110.

The replacement gate 180 may be deposited using typical deposition techniques, for example, atomic layer deposition (ALD), molecular layer deposition (MLD), and chemical vapor deposition (CVD). In an embodiment, the replacement gate 180 may include more than one layer, for example, a conformal layer of a high-k dielectric material such as HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. In an embodiment, a work function metal of a p-FET device may include a metal nitride, for example, titanium nitride or tantalum nitride, titanium carbide titanium aluminum carbide, or other suitable materials known in the art. In an embodiment, the work function metal of an n-FET device may include, for example, titanium aluminum carbide or other suitable materials known in the art. In an embodiment, the work function metal may include one or more layers to achieve desired device characteristics.

In an embodiment, the replacement gate 180 of the lower nanosheet stack 101 may be include a different material than the replacement gate 180 of the upper nanosheet stack 103.

A chemical mechanical polishing (CMP) technique may be used to remove excess material and polish upper surfaces of the structure 100. An upper surface of the structure 100 may include horizontal surfaces of the ILD 160, the gate side spacers 128, the second dielectric 178 and the replacement gate 180.

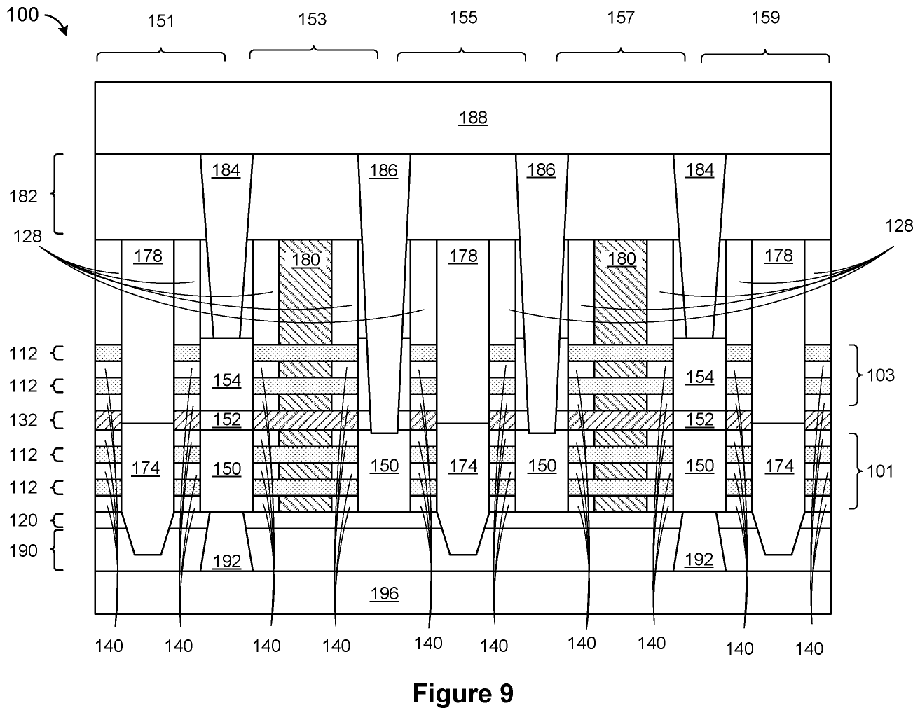

Referring now to FIG. 9, a cross-sectional view of the structure 100 is shown according to an exemplary embodiment. An interlayer dielectric (hereinafter “ILD”) 182 may be formed. Contacts 184, 186 may be formed in the ILD 182. A frontside interconnect layer 188 may be formed. The substrate 102 may be removed. A backside interlayer dielectric (hereinafter “ILD”) 190 may be formed. A contact 192 may be formed in the ILD 190. A backside interconnect layer 196 may be formed.

The ILD 182 may be formed on a upper surface of the structure 100. The ILD 182 may be formed as described for the ILD 152, on the ILD 160, the gate side spacers 128, the upper dielectric layer 178 and the replacement gate 180.

A chemical mechanical polishing (CMP) technique may be used to remove excess material and polish upper surfaces of the ILD 182.

An opening (not shown) may be made in the structure 100 through the ILD 182 and the ILD 160 exposing an upper horizontal surface of the upper source drain 154. The contact 184 may be formed in the opening (not shown) to form a contact to the upper source drain 154.

A second opening (not shown) may be made in the structure 100 through the ILD 182, the ILD 160, the upper source drain 154 and the ILD 152 exposing an upper horizontal surface of the lower source drain 150. The contact 186 may be formed in the opening (not shown) to form a contact to the lower source drain 150.

The contacts 184, 186 may be formed in the opening (not shown) and the second opening (not shown), respectively. The contacts 186, 188 may be formed by method known in the arts. The contacts 186, 188 may have more than one layer. The contacts 184, 186 may include a silicide liner such as Ti, Ni, NiPt, an adhesion liner, such as TiN and a conductive metal, such as W, Co, Ru, or Mo. A chemical mechanical polishing (CMP) technique may be used to remove excess material and polish upper surfaces of the structure 100, exposing an upper horizontal surface of the ILD 182 and upper horizontal surfaces of the contacts 184, 186.

The frontside interconnect layer 188 may be formed on the ILD 182 and on the contacts 184, 186. The frontside interconnect layer 188 may also be referred to as Back end of line (hereinafter “BEOL”) layers. The frontside interconnect layer 188 may include layers of wiring and vias formed above the existing structure, above the contacts 186, 184 and the ILD 182. In an embodiment, the frontside interconnect layer 188 may include 12 or more layers of metal lines and visas. The frontside interconnect layer 188 may be formed using known techniques.

In an embodiment, a carrier wafer (not shown) may be attached to an upper surface of the structure 100, mounted on an upper surface of the frontside interconnect layer 188. The carrier wafer may be attached using conventional wafer bonding process, such as dielectric-to-dielectric bonding or copper-to-copper bonding process. The structure 100 may be flipped and the silicon substrate 102 may be removed.

The structure 100 may be turned such that the carrier wafer (not shown) is now at a bottom, at a lowest point of the structure, and a lower surface of the silicon substrate 102 is now shown at a upper level of the structure for further processing.

The silicon substrate 102 may be selectively removed using a combination of processes steps, such as wafer grinding, CMP, RIE and wet etch process. The final stage of the process may include selectively etching any remaining silicon of the silicon substrate 102 to expose a surface of the BDI 120 and the first dielectric 174. The material used for the etching process may be selective such that the BDI 120 and the first dielectric 174 remain and are not etched.

The ILD 190 may be formed on a (now) upper surface of the structure 100. The ILD 190 may be formed as described for the ILD 152, on the BDI 120 and the first dielectric 174. A chemical mechanical polishing (CMP) technique may be used to remove excess material and polish upper surfaces of the ILD 190.

A third opening (not shown) may be made in the structure 100 through the ILD 190 and the BDI 120 exposing a (now in the flipped position) upper horizontal surface of the lower source drain 150. The contact 192 may be formed in the third opening (not shown) to form a contact to the lower source drain 150.

The backside interconnect layer 196 may be formed on the ILD 190 and on the contact 192. The backside interconnect layer 196 may also be referred to as Back end of line (hereinafter “BEOL”) layers. The backside interconnect layer 196 may include layers of wiring and vias formed above the existing structure, above the contacts 192 and the ILD 190. In an embodiment, the backside interconnect layer 196 may include 12 or more layers of metal lines and visas. The backside interconnect layer 196 may be formed using known techniques.

A chemical mechanical polishing (CMP) technique may be used to remove excess material and polish upper surfaces of the structure 100. An upper surface of the structure 100 may include an upper horizontal surface of the backside interconnect layer 196.

The structure 100 may be now flipped to show the backside interconnect layer 196 as a lowest layer of the structure 100 and the backside interconnect layer 196 as an uppermost layer of the structure 100.

As shown in FIG. 9, there are 2 contacts 184, 2 contacts 186m and 2 contacts 192. There may be any number of contacts 184, 186, 192 on the structure 100.

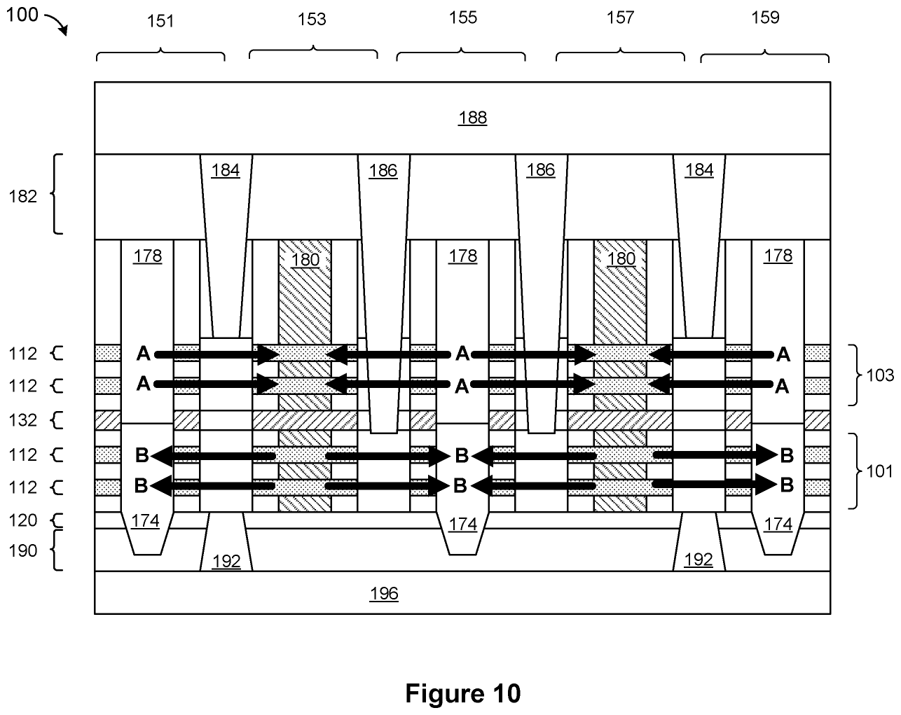

Referring now to FIG. 10, the cross-sectional view the FIG. 9 of the structure 100 is shown according to an exemplary embodiment. Stressor A and stressor B are shown.

In an embodiment, the upper nanosheet stack 103 is a p-FET nanosheet stack and the material of the second dielectric 178 produces a compressive stress, shown as stressor A. The stressor A produces a compressive stress on the channel layers 112 of the upper nanosheet stack 103 of the nanosheet FET regions 153, 157.

In an embodiment, the lower nanosheet stack 101 is an n-FET nanosheet stack and the material of the first dielectric 174 produces a tensile stress, shown as stressor B. The stressor B produces a tensile stress on the channel layers 112 of the lower nanosheet stack 101 of the nanosheet FET regions 153, 157. The compressive or tensile stress is produced through the upper source drain 154 or the lower source drain 150, respectively.

In an alternate embodiment, the upper nanosheet stack 103 is a n-FET nanosheet stack and the material of the second dielectric 178 produces a tensile stress on the channel layers 112 of the upper nanosheet stack 103 of the nanosheet FET regions 153, 157. The lower nanosheet stack 101 is a p-FET nanosheet stack and the material of the second dielectric 178 produces a compressive stress on the channel layers 112 of the upper nanosheet stack 103 of the nanosheet FET regions 153, 157.

The nanosheet FET regions 151, 155 and 159 have been replaced by the vertically aligned first dielectric 174, and the second dielectric 179.

In an embodiment, the upper nanosheet stack 103 and the lower nanosheet stack 101 may both be n-FET, may both be p-FET, may be n-FET over p-FET, or may be p-FET over n-FET. Furthermore, adjacent nanosheet FET regions 151, 153, 155, 157, 159 may be any combination of n-FET and/or p-FET stacked nanosheets. The material of the first dielectric 174 and the second dielectric 178 would accordingly be formed of a material which produces a tensile stress for an adjacent n-FET nanosheet and/or a material which produces a compressive stress for an adjacent p-FET nanosheet.

The resulting structure 100 includes a first dielectric 174 producing longitudinal tensile stress to channel layers 112 of the n-FET of the lower nanosheet stack 101 and a second dielectric 178 producing longitudinal compressive stress to channel layers 112 of the p-FET of the upper nanosheet stack 103. As a result, electron mobility and hole mobility are enhanced by each dielectric stressor, respectively. Thus, performance of both n-FET and p-FET are enhanced simultaneously. A diffusion break of the vertically aligned first dielectric 174 and second dielectric 178 isolates neighboring devices of nanosheet FET regions 153, 157.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a lower set of semiconductor channel layers vertically aligned and stacked one on top of another, the lower set of semiconductor channel layers separated from each other by a gate stack material wrapping around the lower set of semiconductor channel layers;
an upper set of semiconductor channel layers vertically aligned and stacked one on top of another, the upper set of semiconductor channel layers separated from each other by the gate stack material wrapping around the upper set of semiconductor channel layers, the upper set of semiconductor channel layers vertically aligned above the lower set of semiconductor channel layers;
a lower dielectric layer adjacent to a first vertical side and a second vertical side of the lower set of semiconductor channel layers, wherein the first vertical side and the second vertical side of the lower set of semiconductor channel layers are on opposite sides of the lower set of semiconductor channel layers, wherein the lower dielectric layer comprises a first polarity stress on the lower set of semiconductor channel layers; and
an upper dielectric layer adjacent to a first vertical side and a second vertical side of the upper set of semiconductor channel layers, wherein the first vertical side and the second vertical side of the upper set of semiconductor channel layers are on opposite sides of the upper set of semiconductor channel layers and vertically aligned above the lower dielectric layer, wherein the lower dielectric layer comprises a second polarity stress on the upper set of semiconductor channel layers, wherein the first polarity stress and the second polarity stress are opposite polarity stresses from each other.

2. The semiconductor device according to claim 1, wherein
the first polarity stress comprises a tensile stress and the second polarity stress comprises a compressive stress.

3. The semiconductor device according to claim 2, wherein
the upper semiconductor channel layers comprise a negative field effect transistor and the lower semiconductor channel layers comprise a positive field effect transistor.

4. The semiconductor device according to claim 1, wherein
the first polarity stress comprises a compressive stress and the second polarity stress comprises a tensile stress.
the upper semiconductor channel layers comprise a positive field effect transistor and the lower semiconductor channel layers comprise a negative field effect transistor.

5. The semiconductor device according to claim 1, further comprising:
a lower source-drain epitaxy region adjacent to the lower set of semiconductor channel layers; and
an upper source-drain epitaxy region adjacent to the upper set of semiconductor channel layers and vertically aligned above the lower source-drain epitaxy region.

6. The semiconductor device according to claim 1, wherein
the lower dielectric layer extends vertically into a substrate of the semiconductor device.

7. A semiconductor device comprising:
a lower set of semiconductor channel layers vertically aligned and stacked one on top of another, the lower set of semiconductor channel layers separated from each other by a gate stack material wrapping around the lower set of semiconductor channel layers;
an upper set of semiconductor channel layers vertically aligned and stacked one on top of another, the upper set of semiconductor channel layers separated from each other by the gate stack material wrapping around the upper set of semiconductor channel layers, the upper set of semiconductor channel layers vertically aligned above the lower set of semiconductor channel layers;
a lower dielectric layer adjacent to a first vertical side and a second vertical side of the lower set of semiconductor channel layers, wherein the first vertical side and the second vertical side of the lower set of semiconductor channel layers are on opposite sides of the lower set of semiconductor channel layers, wherein the lower dielectric layer comprises a first polarity stress on the lower set of semiconductor channel layers; and
an upper dielectric layer adjacent to a first vertical side and a second vertical side of the upper set of semiconductor channel layers, wherein the first vertical side and the second vertical side of the upper set of semiconductor channel layers are on opposite sides of the upper set of semiconductor channel layers and vertically aligned above the lower dielectric layer, wherein the lower dielectric layer comprises a second polarity stress on the upper set of semiconductor channel layers, wherein
the first polarity stress comprises a tensile stress and the second polarity stress comprises a compressive stress.

8. The semiconductor device according to claim 7, wherein
the upper semiconductor channel layers comprise a negative field effect transistor and the lower semiconductor channel layers comprise a positive field effect transistor.

9. The semiconductor nanosheet device according to claim 7, further comprising:
a lower source-drain epitaxy region adjacent to the lower set of semiconductor channel layers; and
an upper source-drain epitaxy region adjacent to the upper set of semiconductor channel layers and vertically aligned above the lower source-drain epitaxy region.

10. The semiconductor device according to claim 7, wherein
the lower dielectric layer extends vertically into a substrate of the semiconductor device.

11. The semiconductor device according to claim 7, further comprising:
a first contact to an upper surface of the upper source-drain epitaxy; and
a second contact to a lower surface of the lower source-drain epitaxy.

12. A method comprising:
forming a lower stack of nanosheet layers on a substrate and an upper stack of nanosheet layers vertically aligned above the lower stack of nanosheet layers, the first stack and the second stack of nanosheet layers each comprising alternating layers of a sacrificial and a semiconductor channel vertically aligned and stacked one on top of another;
forming a lower dielectric layer vertically adjacent to the lower stack of nanosheet layers, wherein the lower dielectric layer comprises a first polarity stress; and
forming an upper dielectric layer vertically adjacent to the upper stack of nanosheet layers, wherein the upper dielectric layer comprises a second polarity stress which is an opposite polarity of the first polarity stress, wherein the upper dielectric layer is vertically aligned above the lower dielectric layer.

13. The method according to claim 12, wherein
the first polarity stress comprises a tensile stress and the second polarity stress compresses a compressive stress.

14. The method according to claim 13, wherein
the lower semiconductor channel layers comprise a negative field effect transistor and
the upper semiconductor channel layers comprise a positive field effect transistor.

15. The method according to claim 12 further comprising:
forming a lower source-drain epitaxy region adjacent to the lower set of semiconductor channel layers; and
forming an upper source-drain epitaxy region adjacent to the upper set of semiconductor channel layers and vertically aligned above the lower source-drain epitaxy region.

16. The method according to claim 12, wherein
extending the lower dielectric layer vertically into a substrate of the semiconductor device.

17. The method according to claim 12, further comprising:
forming a first contact to an upper surface the upper source-drain epitaxy; and
a second contact to a lower surface of the lower source-drain epitaxy.

18. The method according to claim 12, further comprising:
forming a third contact to an upper surface the lower source-drain epitaxy.

19. The method according to claim 12, further comprising:
removing the alternating sacrificial layers; and
forming a replacement gate where the alternating sacrificial layers were removed.

20. The method according to claim 12, further comprising:
applying a tensile stress on the channel layers of the lower source drain region from the lower dielectric layer; and
applying a compressive stress on the channel layers of the upper source drain region from the upper dielectric layer.
